(19) United States
(12) Patent Application Publication
(10) Pub. No.: US 2012/0098537 A1
(43) Pub. Date: Apr. 26, 2012

(54) High Resolution Nuclear Magnet Resonance with Unknown Spatiotemporal Variations of the Static Magnetic Field

(76) Inventors: Geoffrey Bodenhausen, Paris (FR); Philippe Pelupessy, Montrouge (FR)

(21) Appl. No.: 13/376,741

(22) PCT Filed: Jun. 11, 2010
(86) PCT No.: PCT/EP10/58261

§ 371 Date: Jan. 3, 2012

Related U.S. Application Data
(60) Provisional application No. 61/186,269, filed on Jun. 11, 2009.

(51) Int. Cl. G01R 33/46; G01R 33/32

(52) U.S. Cl. 324/309; 324/318

(57) ABSTRACT

The invention relates to nuclear magnetic resonance spectroscopy (NMR). NMR experiments are usually carried out in homogeneous magnetic fields. In many cases however, the inherent heterogeneity of the samples or living organisms under investigation, and the poor homogeneity of the magnets (particularly when bulky samples must be placed outside their bores), make it virtually impossible to obtain high-resolution spectra. Unstable power supplies and vibrations arising from cooling can lead to field fluctuations in time as well as space. Here it is shown how high-resolution NMR spectra can be obtained in inhomogeneous fields with unknown spatiotemporal variations. The method of the invention, based on coherence transfer between spins, can accommodate spatial inhomogeneities of at least 11 G/cm and temporal fluctuations slower than 2 Hz.

### FIELD OF INVENTION

The present invention relates to a method and a device for performing high resolution nuclear magnetic resonance (NMR) spectroscopy.

### BACKGROUND OF THE INVENTION

Nuclear magnetic resonance spectroscopy is usually carried out in homogeneous magnetic fields. In many cases however, the inherent heterogeneity of samples or living organisms under investigation, and the poor homogeneity of the magnets (particularly when bulky samples must be placed outside their bores), make it virtually impossible to obtain high-resolution spectra. Unstable power supplies and vibrations arising from cooling can lead to field fluctuations in time as well as space.

The present invention aims to improve the situation.

### SUMMARY OF THE INVENTION

To this end, the present invention firstly proposes a method for performing nuclear magnetic resonance spectroscopy, wherein at least one difference of precession frequencies of a homonuclear pair of spins are tracked in a single scan.

More particularly, the implementation of the invention results in that a field gradient echo is formed at an instant in time that is delayed in proportion to said difference of the frequencies of spins.

In an embodiment, the method comprises at least the steps of:
applying a first adiabatic radiofrequency pulse in the presence of a first field gradient followed by a coherent transfer step and applying a second adiabatic pulse with a second field gradient, for encoding resonance frequencies with said difference of frequencies of spins and said first field gradient with possible magnetic field inhomogeneities,
decoding resonance frequencies with a third field gradient having at least a same amplitude as said first field gradient, and
obtaining from said decoding step a gradient echo giving a spectrum of frequency differences in a time domain, in a single scan.

Preferably, the first and second field gradients are identical.

According to another particular feature of the invention, said first (and or second) adiabatic radiofrequency pulse(s) is (are) formed so as to optimise said encoding/decoding steps.

In an embodiment described in details below, the method according to the invention is combined to a J-modulated detection scheme to add a second dimension which can reveal multiplets due to scalar couplings.

The present invention aims also a nuclear magnetic resonance spectrometer, comprising means for performing the method according to the invention.

The present invention is also aimed at a computer program product, stored in a computer memory or on a removable medium able to cooperate with a computer reader, and comprising instructions for running the steps of the method within the sense of the invention.

The software product of the invention can advantageously comprise instructions for generating an adiabatic radiofrequency pulse adapted to optimise the aforesaid encoding/decoding steps.

Thanks to the implementation of the invention, high-resolution NMR spectra can be obtained in inhomogeneous fields with unknown spatiotemporal variations.

### BRIEF DESCRIPTION OF THE DRAWINGS

Other features and advantages of the invention become apparent on reading the following detailed description and examining the appended drawings, in which:

FIG. 1 shows pulse sequences to obtain high-resolution spectra in a single scan in arbitrarily inhomogeneous slowly-fluctuating magnetic fields with unknown spatiotemporal distributions;

FIG. 2 shows a two-dimensional spectra plotted in absolute value mode of (left) propanol CH₃^{c}CH₂^{b}CH₂^{a}OH and (right) butenol CH₂^{b}═CH^{a}CH₂^{d}CH₂^{c}OH;

FIG. 3 shows a same spectrum (left) as in the left part of FIG. 2D, taken with n_{E}=1 and G_{D}=2.4 G/cm (right: spectrum taken under the same conditions, except that n_{E}=2 and G_{D}=4 G/cm) and the columns shown on the right exemplify the gain in resolution that can be obtained by increasing the number of encoding gradients; the line-width has improved from 76 Hz (0.13 ppm) on the left to 41 Hz (0.07 ppm) on the right;

FIG. 4 shows a spectrum of propanol (A) recorded with the method shown in FIG. 1D, with a permanent gradient of 2.75 G/cm applied along the z-axis throughout the entire sequence, without switching the decoding or encoding gradients (the adiabatic rf pulses had durations of 18 ms and sweep widths of 40 kHz); FIG. 4B shows the same as FIG. 4A but with twice the amplitude of the permanent gradient (5.5 G/cm) and twice the rf sweep width; FIG. 4C shows the same as FIG. 4B but each adiabatic pulse is replaced by three 6 ms adiabatic pulses as in FIG. 1E; FIG. 4D shows the same as FIG. 4C but with a permanent gradient of 11 G/cm and twice the sweep width of the adiabatic pulses (on the right are the corresponding single quantum spectra).

### MORE DETAILED SPECIFICATION

Nuclear magnetic resonance (NMR) is arguably one of the most versatile and ubiquitous forms of spectroscopy. Year after year, magnetic resonance imaging (MRI) reveals more surprising insights into morphology, function, and metabolism. Most applications, regardless of whether they are concerned with inanimate solids or liquids or with living organisms, rely on the use of very homogeneous magnetic fields B₀ with spatial variations below about 10⁻⁹, so that subtle differences in the environment of various nuclei, leading to chemical shifts and couplings, can be made apparent. However, it is often not possible to work under ideal conditions. For example, sufficiently homogeneous fields are difficult to achieve in ex situ NMR where the object under investigation is placed outside the magnet (1, 2), in very high fields induced by resistive or hybrid magnets (3, 4), and in samples (including animals and human beings) which are moving because of pulsating arteries or respiration, not to mention the discontinuities of the magnetic susceptibility due to voids and surgical implants (5, 6).

Many techniques have been proposed to acquire high-resolution spectra under adverse conditions. Spin-echoes (7, 8) can refocus the effects of inhomogeneous B₀ fields, and reveal couplings that lead to echo modulations (9-11). If the field's spatial distribution is known, the B₀ inhomogeneity may be compensated by using a radio-frequency (rf) field designed to have a similar, spatially correlated profile. Two such approaches have been described. In the first one, the rf-field B₁(r) profile is designed to match the B₀(r) profile (12-14). The dephasing caused by the rf-field can then be refocused by rephasing in the main B₀ field. In the second approach, the inhomogeneities are compensated by manipulating the phases of the magnetization vectors associated with different voxels in the presence of a known gradient, in the manner of multidimensional single-scan experiments (15, 16). In either case, the field B₀(r) must be time-independent, and its spatial profile must be known, which constitutes a serious handicap.

In the present invention, high-resolution spectra in inhomogeneous fields are obtained by tracking the differences of the precession frequencies (17, 18) of two spins in a single scan, in a way that is closely related to the ultrafast multidimensional experiments developed by Frydman et al (19) and improved in reference (20) (the content of which is incorporated herein by reference thereto). The experiment functions regardless B₀ field profile. Spatial inhomogeneities of at least 11 G/cm can be accommodated. This corresponds to a frequency distribution of about 42 kHz (or 70 ppm for a 600 MHz resonance frequency) for a spherical sample of 1 cm in diameter. Combining this technique with the J-modulated detection scheme of Giraudeau and Akoka (21) adds a second dimension which reveals multiplets due to scalar couplings.

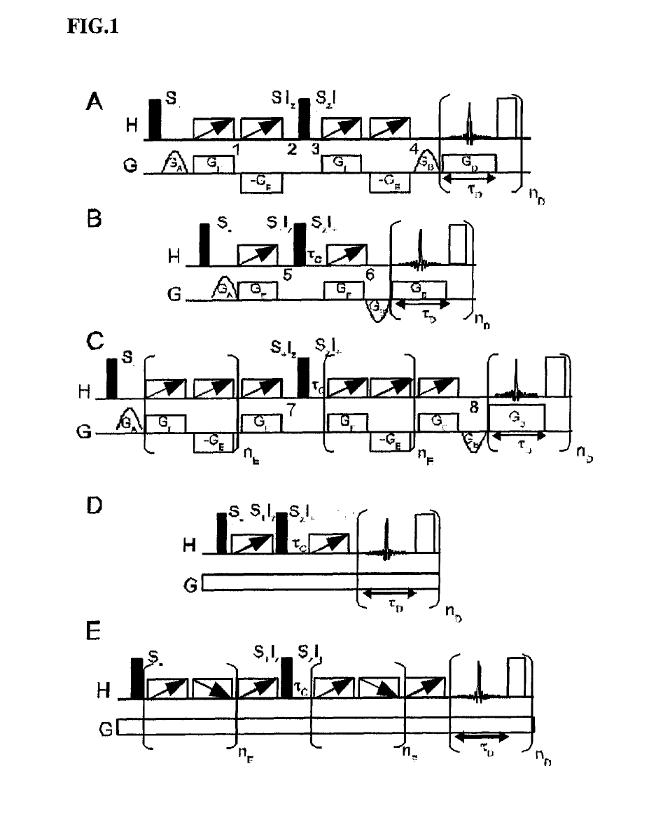

As in the two-dimensional single-scan experiments, the evolution under the chemical shifts needs to be intertwined with gradient encoding (22). Let S and I constitute a homonuclear pair of spins. When a linearly swept adiabatic refocusing pulse is applied in the presence of a gradient to a coherence S₊ with coherence order p=+1 belonging to the manifold of S-spin transitions, as shown in FIG. 1A, the resulting phase at time t₁ is given by (20):

φ₁=α{Ω_{S}+δω(r)+Γ_{E}(r)}² (1)

where Ω_{S} is the chemical shift of the S spin, δω(r)=−γ_{S}B₀(r) the (unknown) spatially dependent frequency induced by the inhomogeneous B₀ field, Γ_{E}(r)=γ_{S}G_{E}·r the (known) frequency induced by the encoding gradient G_{E}={G_{Ex}k, G_{Ey}i, G_{Ez}j} and α=σ_{ad}/Δω_{ad} the ratio of the duration σ_{ad} and sweep width Δω_{ad} of the adiabatic inversion pulse. A second identical pulse combined with an opposite gradient then leads to a phase at time t₂:

φ₂=4α{Ω_{S}+δω(r)}Γ_{E} (2)

In FIG. 1, filled and open vertical rectangles represent π/2 and π pulses. The rectangles with sloping arrows indicate adiabatic frequency swept refocusing pulses. G_{E} and G_{D} are encoding and decoding gradients. The gradients G_{A} and G_{B} of equal area serve to select the desired coherence pathways (they must be opposite for (B) and (C) and identical for (A)). The delay σ_{C} serves to compensate for the evolution under the inhomogeneous B₀ field during G_{A} and G_{B}. Increasing G_{B} and prolonging σ_{C} by σ_{D}/2 shift the signals at zero frequency toward the centre of the gradient G_{D}. Sequences (D) and (E) are adaptations of (B) and (C), for situations where a permanent gradient is dominant. Adiabatic pulses with down-pointing arrows have reversed sweep directions. The phases of the n pulses during decoding are alternated between x to −x every two pulses (21). In these examples, π/2 pulses are used to achieve transfer of coherence, so that the spins need to be scalar coupled. Other sequences can be used, such as total correlation spectroscopy (TOCSY). The signals during even (or odd) decoding gradients are arranged in sequential order, to give a two-dimensional array. The gradient echoes that are formed during each decoding gradient appear in a temporal sequence that corresponds to the peaks in the spectrum. The scalar coupling pattern in the other dimension is obtained by performing a Fourier transformation as a function of the index of the decoding gradients.

The coherence can then be transferred (in the example of FIG. 1 by a simple π/2 pulse) from S₊ to I₋ with coherence order p=−1 through any spin-spin coupling, exploiting for example a scalar interaction J_{IS}. If there are no scalar couplings, it might be possible to use demagnetizing fields which can manifest themselves as intermolecular dipolar interactions (23, 24). After an identical block comprising two more pulses and gradients, the total accumulated phase at time t₄ will be:

φ₄=4α{Ω_{S}+δω(r)}Γ_{E}(r)−4α{Ω_{I}+δω(r)}Γ_{E}(r)=4α{Ω_{S}−Ω_{I}}Γ_{E}(r) (3)

This phase does not depend on the spatial variation δω(r) due to the inhomogeneous static field. The phase φ₄ can be refocused by a decoding gradient G_{D}. A gradient echo will be formed at an instant in time that will be delayed in proportion to the difference Ω_{S}−Ω_{I} between the frequencies of spins S and I. Although this feature is reminiscent of zero-quantum spectroscopy, it should be noted that the echoes arise simply from the differential evolution of two single quantum (SQ) coherences (18). During the decoding gradient G_{D} in the scheme of FIG. 1A, the coherences will continue to precess under the field inhomogeneities, thus preventing complete refocusing. An improved scheme is shown in FIG. 1B. Instead of applying two adiabatic pulses before and after coherence transfer, only one is applied, which leads to a phase:

φ₆=α{Ω_{S}+δω(r)+Γ_{E}(r)}²−α{Ω_{I}+δω(r)+Γ_{E}(r)}²=αΩ_{S}²−αΩ_{I}²+2α(Ω_{S}−Ω_{I}){Γ_{E}(r)+δω(r)} (4)

The difference Ω_{S}—Ω_{I} between the chemical shifts of spins I and S is now encoded not only by the gradient G_{E} but also by the B₀ inhomogeneity. During a decoding gradient G_{D} with the same amplitude as the encoding gradient G_{E}, the phase is then:

φ_{D}(t_{D})=αΩ_{S}²−αΩ_{I}²+2α(Ω_{S}−Ω_{I}){Γ_{E}(r)+δω(r)}−t_{D}{Ω_{I}+Γ_{E}(r)+δω(r)} (5)

At t_{D}=2α(Ω_{S}−Ω_{I}) an echo results because the phase is independent of δω(r). Thus a spectrum of frequency differences is obtained in the time domain in a single scan. The phase of this echo is

φ_{D}{t_{D}=2α(Ω_{S}−Ω_{I})}=αΩ_{S}²+αΩ_{I}²−2αΩ_{I}Ω_{S}=α(Ω_{S}−Ω_{I})² (6)

A hybrid scheme is shown in FIG. 1C. A bipolar gradient pair with adiabatic pulses that is repeated n_{E} times is inserted before each adiabatic pulse of FIG. 1B. The resulting phase at time t₇ is:

$$\begin{matrix}{ϕ}_{7} = 2 {n}_{E} α ( {Ω}_{S} - {Ω}_{I } ) {Γ}_{E} ( r ) + α {Ω}_{S}^{2} - α {Ω}_{I}^{2} + 2 α ( {Ω}_{S} - {Ω}_{I} ) \{ {Γ}_{E} ( r ) + δ ω ( r ) \} \\ = α {Ω}_{S}^{2} - α {Ω}_{I}^{2} + 2 α ( {Ω}_{S} - {Ω}_{I} ) \{ ( 2 {n}_{E} + 1 ) {Γ}_{E} ( r ) + δ ω ( r ) \}\end{matrix} \qquad ( 7 )$$

The decoding gradient should have an amplitude that is (2n_{E}+1) times as large as the encoding gradient, i.e., G_{D}=(2n_{E}+1)G_{E}, in order to cancel the effects of the inhomogeneities δω(r). The sequence of FIG. 1C is less sensitive to translational diffusion than the experiment of FIG. 1B (25).

As can be seen from Eq. 5, scheme (B) does not require any switched field gradients, provided the inhomogeneities are sufficiently large to cause sharp echoes. This could have implications for measurements in stray magnetic fields (26) or other permanent gradients. FIGS. 1D and 1E show adaptations of FIGS. 1B and 1C, for situations with a permanent gradient. In FIG. 1E the sweep direction of the second adiabatic pulse in each repeated block is inverted. Both schemes lead to a phase φ₆ of Eq. 4, but the latter limits losses due to diffusion (25).

All schemes can be extended from one to two dimensions by appending n_{D} repetitions of a block comprising a decoding gradient followed by a π pulse in order to observe a train of spin echoes (21). A Fourier transformation of this echo train reveals (convoluted) multiplets due to scalar couplings in a second dimension. This option requires ca. 500 instead of ca. 50 ms for the basic 1D experiment. The simplest one-dimensional spectrum corresponds to the signal acquired during the first decoding gradient.

Shapira et al, (4) proposed schemes for measurements in fluctuating resistive magnets. The resolution of correlation spectra can be improved, either by compensating for (known) inhomogeneities with tailored rf-fields, or by exploiting echoes following coherence transfer from carbon-13 to proton nuclei. The latter scheme is related to the method of the invention, although in their case the effects of inhomogeneities are cancelled only at one point in the acquisition period.

The experiments of FIG. 1C have been tested by applications to samples containing 5% 1-propanol (CH₃CH₂CH₂OH) and 5% 3-buten-1-ol (CH₂═CHCH₂CH₂OH, henceforth simply called butenol) in CDCl₃.

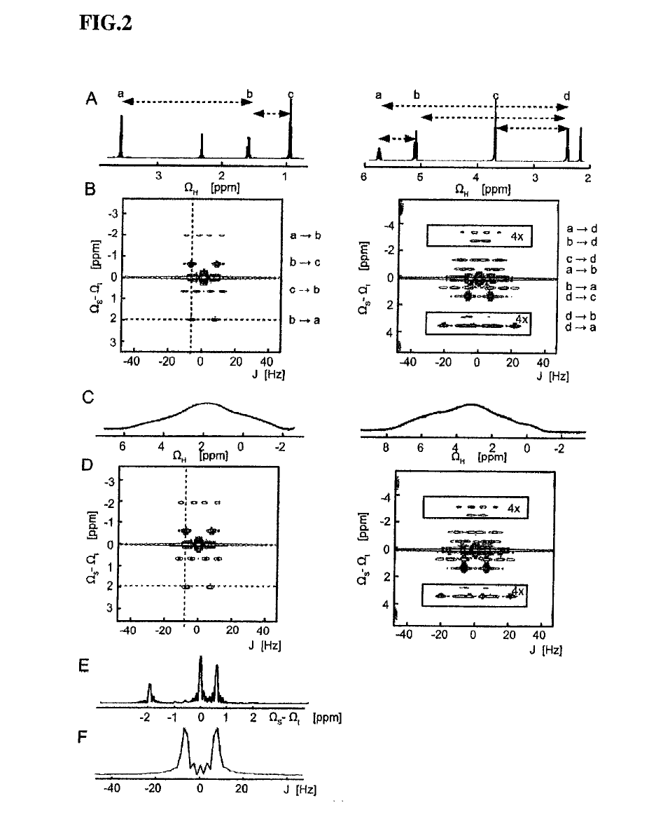

FIG. 2 shows a two-dimensional spectra plotted in absolute value mode of (left) propanol CH₃^{c}CH₂^{b}CH₂^{a}OH and (right) butenol CH₂^{b}═CH^{a}CH₂^{d}CH₂^{c}OH both taken in ca 500 ms with the single-scan method of FIG. 1C. (B) and (D) were obtained in homogeneous and inhomogenous B₀ fields, respectively, as evidenced by the conventional proton spectra in (A) (with line-widths on the order of 2 Hz, recorded in a well-shimmed static field) and in (C) (where the line-widths were degraded to ca 4 ppm or 2.4 kHz at 600 MHz). The resonances of spins S and I, labeled a, b, c and d, correspond to single-quantum coherences that evolve during the encoding and decoding blocks of FIG. 1; their scalar coupling patterns appear along the horizontal dimension and carry the same labels (S→I). The arrows in (A) indicate all difference frequencies between scalar-coupled spins that can be observed. The top arrows correspond to the outer lines in the spectrum, the bottom arrows to the smallest frequency differences (inner lines). The line at zero frequency corresponds to coherences that are refocused but not transferred from one spin to another. Both spectra have been recorded with n_{E}=1, gradients applied simultaneously along z and y with strengths G_{E}=0.8 G/cm and G_{D}=2.4 G/cm. The adiabatic pulses of 6 ms had a Wideband Uniform Rate and Smooth Truncation (WURST) profile (28), and sweep-widths of 14 and 20 kHz for propanol and butenol, respectively. (E) Columns taken parallel to the vertical t₁ or ω₁ domain, taken along the dotted lines of the 2D spectra of propanol in homogeneous (red lines) and inhomogeneous fields (black lines), showing differences of chemical shifts in the spectrum of propanol. (F) Rows taken parallel to the horizontal ω₂ domain, showing a multiplet due to scalar couplings with a full width at half height of 3.5 Hz, for n_{D}=64 (t₂^{max}=337 ms).

The spectra of FIGS. 2A and 2B have been obtained in a carefully shimmed homogeneous field. The resonances labeled a-d give rise to combination lines (differences in chemical shifts), i.e., 4 peaks in propanol and 8 in butenol. In the vertical dimension, the spectra are symmetric with respect to ω₁=0, because each transfer from spin S to I is accompanied by a transfer in the opposite direction. The central peak at ω₁=0 arises from magnetization that is refocused but not transferred from one spin to another.

FIGS. 2C and 2D show spectra obtained with the same method in an inhomogeneous field after deliberately missetting the shim currents. Yet the results of the single-scan experiments according to the invention are virtually indistinguishable. The experiments have been repeated using several shim settings, invariably leading to similar spectra, as can be seen from the cross-sections in FIGS. 2E and 2F. As with all 2D single-scan experiments, the signal-to-noise ratio decreases in proportion to the square root of the number of points observed in the indirect dimension, when compared to a 1D spectrum taken under properly shimmed conditions. If the signal-to-noise ratio is poor, the experiments can be repeated for signal averaging, even if the B₀ inhomogeneities vary in time, provided the fluctuations are slow compared to the time it takes to acquire each scan. For a simple one-dimensional spectrum, about 50 ms suffice. Thus, assuming that the information must be acquired within 10% of the period of the fastest fluctuations, the spectrum of the stochastic variations must be limited to 2 Hz. This should be useful for NMR spectra obtained in resistive Bitter or hybrid magnets, which suffer from random fluctuations due to the power supply and to low-frequency vibrations associated with the circulation of cooling water.

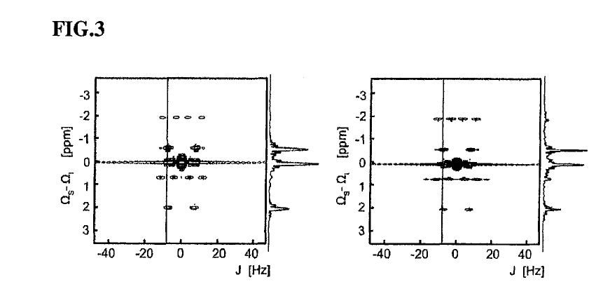

The resolution, as measured by the full line-width at half-height in the vertical (chemical shift) dimension (t₁ or ω₁) of 1-propanol in FIG. 2E is 60 μs, for a decoding gradient G_{D} of 4 ms. This corresponds to a resolution of 76 Hz (0.13 ppm) over a frequency range of ±2500 Hz (±4.2 ppm). The resolution of the spectra can be improved by increasing the amplitudes of both encoding and decoding gradients (provided the frequency sweep of the adiabatic pulses covers the frequency range induced by the encoding gradients) or, as shown in FIG. 3, by increasing n_{E} and the strength of the decoding gradients. The frequency range can be increased by extending the sweep width of the adiabatic pulses, albeit at the expense of the resolution, unless one also increases the strength of both encoding and decoding gradients (27—the content of which is incorporated herein by reference thereto). The resolution in the ω₂ dimension is determined by the number n_{D} of points acquired in the t₂ dimension, like in other forms of 2D spectroscopy.

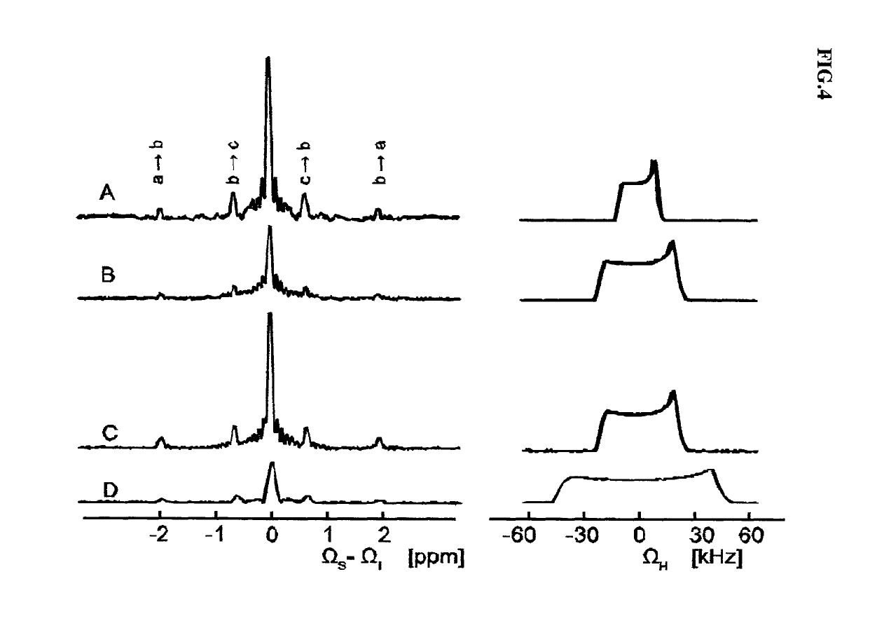

In order to mimic a gradient that cannot be switched off, the scheme of FIG. 1D has been applied, in the presence of a permanent gradient, or more accurately, a pulsed field gradient that was switched on before the experiment and stopped immediately after observing the signals has been applied. The echo corresponding to zero frequency appears at σ_{C} after the start of signal acquisition. Only one-dimensional spectra revealing combinations of chemical shifts in propanol have been recorded (to avoid using prolonged strong gradients). The sample height was decreased to 18 mm, so that the line-shape was further deteriorated by susceptibility effects at the edges. FIG. 4A shows the resulting spectra in the presence of a gradient G_{z}=2.75 G/cm (˜35 ppm or 21 kHz across the sample). Signals arising from coherence transfer are indicated by arrows. The duration of the adiabatic pulses was 18 ms and their sweep width 40 kHz. When the gradient strength is doubled to 5.5 G/cm (˜70 ppm or ˜42 kHz) together with a doubling of the adiabatic sweep width, there is some loss of intensity due to diffusion (FIG. 4B). These losses can be reduced with the scheme of FIG. 1E, as shown in FIG. 4C for a total of 6 adiabatic pulses of 6 ms duration (instead of two otherwise identical pulses of 18 ms each used for FIG. 4B). The line-width in FIG. 4C is about 70 Hz. Increasing the gradient strength further to 11 G/cm (˜140 ppm or ˜84 kHz) leads to the spectrum in FIG. 4D. In this case, the signal amplitude suffers not only from diffusion losses, but also from the limited rf amplitude (25 kHz) of the initial π/2 pulse. In stronger gradients, one should use a large number of short inversion pulses that cover a very broad bandwidth with the desired phase-profile. In addition, the (possibly frequency swept) π/2 pulses should excite the full bandwidth uniformly, bearing in mind that a linear dependence of the phase with respect to offset is allowed.

### LIST OF CITED REFERENCES

1. G. Eidmann, R. Savelsberg, P. Blumler, B. Blümich, J. Magn. Reson. A 122, 104-109 (1996).
2. B. Blümich, J. Perlo, F. Casanova, Prog. Nucl. Magn. Reson. Spectrosc. 52, 197-269 (2008).
3. Y. Y. Lin, S. Ahn, N. Murali, W. Brey, C. R. Bowers, W. S. Warren, Phys. Rev. Let. 85, 3732-3735 (2000).
4. B. Shapira, K. Shetty, W. W. Brey, Z. Gan, L. Frydman, Chem. Phys. Let. 442, 478-482 (2007).
5. I. J. Cox, G. M. Bydder, D. G. Gadian, I. R. Young, E. Proctor, S. R. Williams, I. Hart, J. Magn. Reson. 70, 163-168 (1986).
6. C. E. Mountford, S. Doran, C. L. Lean, P. Russell, Chem. Rev. 104, 3677-3704 (2004).
7. E. L. Hahn, Phys. Rev. 80, 580 (1950).
8. H. Y. Carr, E. M. Purcell, Phys. Rev. 94, 630-638 (1954).
9. E. L. Hahn, D. E. Maxwell, Phys. Rev. 88, 1070 (1952).
10. R. L. Vold, S. O. Chan, J. Chem. Phys. 53, 449-451 (1970).
11. R. Freeman, H. D. W. Hill, J. Chem. Phys. 54, 301-313 (1971).
12. C. A. Meriles, D. Sakellariou, H. Heise, A. J. Moule, A. Pines, Science 293, 82-85 (2001).
13. V. Demas, C. Meriles, D. Sakellariou, S. I. Han, J. Reimer, A. Pines, Concepts Magn. Reson. B 29B, 137-144 (2006).
14. J. Perlo, V. Demas, F. Casanova, C. A. Meriles, J. Reimer, A. Pines, B. Blümich, Science 308, 1279-1279 (2005).
15. B. Shapira, L. Frydman, J. Am. Chem. Soc. 126, 7184-7185 (2004).
16. B. Shapira, L. Frydman, J. Magn. Reson. 182, 12-21 (2006).
17. A. Wokaun, R. R. Ernst, Chem. Phys. Let. 52, 407-412 (1977).
18. K. Nagayama, K. Wüthrich, R. R. Ernst, Biochem. Biophys. Res. Commun. 90, 305-311 (1979).
19. L. Frydman, T. Scherf, A. Lupulescu, Proc. Nat. Acad. Sci. U.S.A. 99, 15858-15862 (2002).
20. P. Pelupessy, J. Am. Chem. Soc. 125, 12345-12350 (2003).
21. P. Giraudeau, S. Akoka, J. Magn. Reson. 186, 352-357 (2007).
22. L. Frydman, A. Lupulescu, T. Scherf, J. Am. Chem. Soc. 125, 9204-9217 (2003).
23. S. Vathyam, S. Lee, W. S. Warren, Science 272, 92-96 (1996).
24. G. Galiana, R. T. Branca, W. S. Warren, J. Am. Chem. Soc. 127, 17574-17575 (2005).
25. P. Giraudeau, S. Akoka, J. Magn. Reson. 195, 9-16 (2008).
26. P. J. McDonald, Prog. Nucl. Magn. Reson. Spectrosc. 30, 69-99 (1997).
27. P. Pelupessy, L. Duma, G. Bodenhausen, J. Magn. Reson. 194, 169-174 (2008).
28. E. Kupce, R. Freeman, J. Magn. Reson. A 115, 273-276 (1995).

1. A method for performing nuclear magnetic resonance spectroscopy, wherein at least one difference of precession frequencies of a homonuclear pair of spins are tracked in a single scan.

2. The method of claim 1, wherein a field gradient echo is formed at an instant in time that is delayed in proportion to said difference of the frequencies of spins.

3. The method of claim 1, comprising at least the steps of:
applying a first adiabatic radiofrequency pulse in the presence of a first field gradient followed by a coherent transfer step and a second adiabatic pulse with a second field gradient, for encoding resonance frequencies with said difference of frequencies of spins and said first field gradient with possible magnetic field inhomogeneities,
decoding resonance frequencies with a third field gradient having at least a same amplitude as said first field gradient, and
obtaining from said decoding step a gradient echo giving a spectrum of frequency differences in a time domain, in a single scan.

4. The method of claim 3, wherein a form of said adiabatic radiofrequency pulse is chosen so as to optimise said encoding/decoding steps.

5. The method of claim 1, combined to a J-modulated detection scheme to add a second dimension revealing multiplets due to scalar couplings.

6. A nuclear magnetic resonance spectrometer, comprising means for performing the method according to claim 1.

7. A software product adapted to be stored in a memory of a processor unit, in particular of a nuclear magnetic resonance spectroscope, or in a removable memory medium adapted to cooperate with a reader of said processor unit, comprising instructions for implementing the method according to claim 1.

8. The software product of claim 7, comprising instructions for generating an adiabatic radiofrequency pulse adapted to optimise said encoding/decoding steps.
